(19) United States
(12) Patent Application Publication
(10) Pub. No.: US 2016/0286673 A1
(43) Pub. Date: Sep. 29, 2016

(54) COVER WINDOW AND DISPLAY DEVICE INCLUDING THE SAME

(71) Applicant: SAMSUNG DISPLAY CO., LTD., Yongin-si (KR)

(72) Inventor: Seung Wook NAM, Cheonan-si (KR)

(21) Appl. No.: 14/859,214

(22) Filed: Sep. 18, 2015

(30) Foreign Application Priority Data
Mar. 25, 2015 (KR) 10-2015-0041811

(51) Int. Cl. H05K 5/03; B32B 7/02; B32B 3/26; H05K 5/00

(52) U.S. Cl. CPC H05K 5/03; H05K 5/0017; B32B 7/02; B32B 3/266; B32B 2307/412; B32B 2307/536; B32B 2457/20

(57) ABSTRACT

A cover window includes a hardness compensation layer, a base film on the hardness compensation layer, and a coating layer on the base film, wherein an elastic coefficient of the hardness compensation layer is greater than an elastic coefficient of the base film.

### CROSS-REFERENCE TO RELATED APPLICATION

This application claims priority to and the benefit of Korean Patent Application No. 10-2015-0041811, filed in the Korean Intellectual Property Office on Mar. 25, 2015, the entire content of which is incorporated herein by reference.

### BACKGROUND

1. Field

The following description relates to a cover window and a display device including the same.

2. Description of the Related Art

Recently, various mobile electronic apparatuses, such as a portable phone, a navigation device, a digital camera, an electronic book, a portable game console, or various kinds of terminals, to which a liquid crystal display (LCD) or an organic electroluminescent display (organic light emitting diode, OLED) is applied as a display device, have been used.

In a general display device used in a mobile apparatus, a cover window is transparently constituted so that a user may see a display unit is provided at a front of a display panel. Because the cover window is a constitution formed at the outermost side of the device, the cover window should be strong against external impact so as to protect the display panel and the like in the apparatus.

Moreover, instead of an existing manner where a switch or a keyboard is used as an input device, recently, a structure where a touch panel integrated with a display image is used has come into wide use, and thus, cases where a surface of the cover window comes into contact with a finger and the like frequently occur, which may require stronger hardness.

Further, recently, research of a flexible display device has been actively conducted, and it is desirable that a cover window applied to this display device be formed of a foldable member having ductility.

The above information disclosed in this Background section is only for enhancement of understanding of the background of the invention and therefore it may contain information that does not form the prior art that is already known in this country to a person of ordinary skill in the art.

### SUMMARY

Aspects of the present invention are directed toward a foldable cover window for a display device having surface hardness at a preset level or higher, and a display device including the same.

According to an exemplary embodiment of the present invention, there is provided a cover window including: a hardness compensation layer, a base film on the hardness compensation layer, and a coating layer on the base film, wherein an elastic coefficient of the hardness compensation layer is greater than an elastic coefficient of the base film.

In an embodiment, a material of the hardness compensation layer includes a metal and/or a metal compound.

In an embodiment, the hardness compensation layer is a lattice.

In an embodiment, a material of the hardness compensation layer includes an inorganic compound.

In an embodiment, the hardness compensation layer is a plate.

In an embodiment, a thickness of the hardness compensation layer is about 10% or less of a thickness of the base film.

In an embodiment, a thickness of the hardness compensation layer is less than a sum of thicknesses of the base film and the coating layer.

In an embodiment, a thickness of the cover window is about 500 μm or less.

According to an exemplary embodiment of the present invention, there is provided a display device including: a display panel, and a cover window on the display panel, wherein the cover window includes: a hardness compensation layer, a base film on the hardness compensation layer, and a coating layer on the base film.

In an embodiment, an elastic coefficient of the hardness compensation layer is greater than an elastic coefficient of the base film.

In an embodiment, a material of the hardness compensation layer includes a metal and/or a metal compound.

In an embodiment, the hardness compensation layer is a lattice.

In an embodiment, a material of the hardness compensation layer includes an inorganic compound.

In an embodiment, the hardness compensation layer is a plate.

In an embodiment, a thickness of the hardness compensation layer is about 10% or less of a thickness of the base film.

In an embodiment, a thickness of the hardness compensation layer is less than a sum of thicknesses of the base film and the coating layer.

In an embodiment, a thickness of the cover window is about 500 μm or less.

In an embodiment, the display panel includes a gate line, a semiconductor layer on the gate line, and a data line on the semiconductor layer, and a width of the lattice is about 90% or less of a width of any one of the gate line and the data line.

The cover window and the display device including the same may be bent and have a surface hardness at a preset level or higher through a hardness compensation layer positioned on a rear surface of a base film.

### BRIEF DESCRIPTION OF THE DRAWINGS

FIG. 1 is a schematic cross-sectional view of a display device according to an exemplary embodiment of the present invention.

FIG. 2 is a schematic cross-sectional view of a display device according to another exemplary embodiment of the present invention.

FIG. 3 is a graph of a loss factor of front transmittance according to a width change.

FIG. 4 is a graph of bending stiffness according to a thickness.

FIG. 5 is a graph of bending stiffness according to a thickness of a cover window according to an exemplary embodiment of the present invention.

FIG. 6 is a graph of a defect occurrence ratio according to a thickness of a cover window according to another exemplary embodiment of the present invention.

### DETAILED DESCRIPTION

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

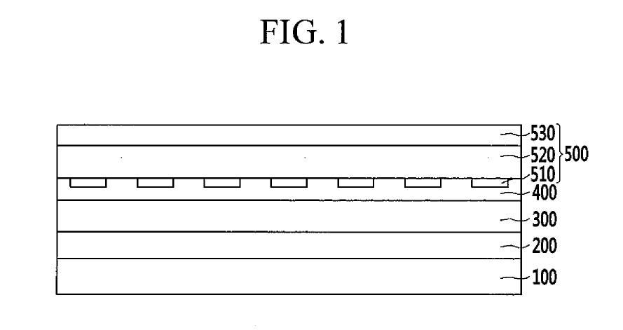

In the drawings, the thickness of layers, films, panels, regions, etc., are exaggerated for clarity. Like reference numerals designate like elements throughout the specification. Hereinafter, a cover window according to an exemplary embodiment of the present invention and a display device including the same will be described with reference to FIG. 1. FIG. 1 is a schematic cross-sectional view of a display device according to an exemplary embodiment of the present invention.

A display device 1000 according to the exemplary embodiment of the present invention may be a flexible or foldable display device but is not limited thereto, and may be a flat panel display device.

The display device 1000 includes a flexible display panel 100 displaying an image, a touch sensing layer 200, a polarizing plate 300, and a cover window 500. The polarizing plate 300 and the cover window 500 according to the exemplary embodiment of the present invention may be combined (e.g., adhered or coupled) by an adhesive layer 400.

The flexible display panel 100 includes a plurality of pixels displaying an image treated in the flexible display device 1000. For example, in the case in which the flexible display device 1000 according to the present exemplary embodiment is a mobile terminal such as a mobile phone, an image such as a user interface (UI) or a graphic user interface (GUI) relating to a conversation may be displayed.

The flexible display panel 100 includes a flexible substrate formed of a plastic material having excellent heat resistance and durability, such as polyethylene naphthalate (PEN), polycarbonate (PC), polyarylate (PAR), polyether imide (PEI), polyether sulfone (PES), polyimide (PI), poly(methylmethacrylate) (PMMA), and/or the like. Further, the flexible display panel is not limited thereto, but the flexible display panel 100 may include flexible substrates formed of various suitable flexible materials.

Furthermore, the flexible display panel 100 may include a flexible substrate where a plurality of thin film transistors, a plurality of gate lines, a plurality of data lines, and a plurality of pixel electrodes are disposed, a flexible substrate where a plurality of color filters and a common electrode are disposed, and a liquid crystal layer interposed between the two substrates.

Further, the flexible display panel 100 may include a flexible substrate where a plurality of thin film transistors, a plurality of gate lines, a plurality of data lines, a plurality of pixel electrodes, and a common electrode are disposed. In this case, a microcavity is formed between the pixel electrode and the common electrode, and a liquid crystal layer may be formed in the microcavity.

Further, the flexible display panel 100 may include a plurality of thin film transistors, a plurality of gate lines, a plurality of data lines, and a plurality of organic light emitting diodes disposed on the flexible substrate.

The touch sensing layer 200 is positioned on the flexible display panel 100. The touch sensing layer 200 senses a touch by a user. The touch sensing layer 200 may sense the touch when an object actually approaches the touch sensing layer 200 or comes into contact with the touch sensing layer 200. Herein, contact includes the case in which an external object such as a user's hand comes into direct contact with the touch sensing layer 200, and the case in which the external object approaches the touch sensing layer 200 or moves in an approaching state (e.g., hovering).

Furthermore, in the present exemplary embodiment, the touch sensing layer 200 is disposed on the flexible display panel 100, but is not limited thereto, and the touch sensing layer 200 may be disposed in the flexible display panel 100. Further, the touch sensing layer 200 may be positioned in the flexible substrate to be attached onto the flexible display panel 100. Further, the touch sensing layer 200 may be disposed in the window 500.

The polarizing plate 300 is positioned on the touch sensing layer 200. The polarizing plate 300 may reduce external light reflection to increase a contrast ratio of the display device.

The window 500 is positioned on the polarizing plate 300, and serves to protect the flexible display panel 100 and the touch sensing layer 200 from external force and an external contamination material. The adhesive layer 400 for attaching the window 500 may be positioned between the window 500 and the polarizing plate 300.

Further, a barrier layer absorbing an impact from the outside to reduce or prevent damage of the flexible display panel 100 and the touch sensing layer 200 due to the impact from the outside may be positioned at a rear surface of the flexible display panel 100. In this case, the barrier layer may be formed of a material containing air to absorb the impact, such as a cushion or a sponge. Further, the barrier layer may serve to attach the flexible display panel 100 to other parts, for example, the case, and in this example, the barrier layer may include the adhesive layer to be attached to the other parts.

The window 500 according to the exemplary embodiment of the present invention includes a hardness compensation layer 510, a base film 520 positioned on the hardness compensation layer 510, and a coating layer 530 positioned on the base film 520. According to the exemplary embodiment, a separate functional layer positioned on the coating layer 530 may be further included.

The hardness compensation layer 510 provides hardness that is strong against external force or impact to the window 500. In the case of the window 500, a base film formed of a plastic material is used to implement flexibility, but has durability that is weaker than that of glass, and thus it is desirable to reinforce durability. Therefore, the thickness of the base film may be increased to reinforce durability, but in this case, there is a problem in that bending stiffness is increased to reduce flexibility of the flexible film. Herein, bending stiffness represents restoration force after bending.

Accordingly, in an exemplary embodiment of the present invention, flexibility is implemented through the base film having a small thickness, and hardness of the window is improved (e.g., increased) through the hardness compensation layer 510 positioned at a rear surface of the base film 520.

The hardness compensation layer 510 may be formed of any material for improving hardness of the window 500 but, for example, a material having a high elastic coefficient, such as a metal or a metal compound, may be used. For example, the metal may be aluminum (Al), iron (Fe), chromium (Cr), and/or the like, and the metal compound may be chromium oxide (CrOx) and/or the like.

A planar type (kind) of the hardness compensation layer 510 may be a lattice or a lattice type (e.g., in lattice shape or a shape of a lattice). This is because in the case in which the material of the hardness compensation layer 510 is an opaque material such as a metal or a metal compound, there is a possibility where the hardness compensation layer is seen from the outside. However, like the exemplary embodiment of the present invention, in the case of the opaque hardness compensation layer 510, when the hardness compensation layer is formed as the lattice or lattice type (kind), the hardness compensation layer may be prevented or substantially prevented from being seen from the outside.

For example, the lattice type of the hardness compensation layer 510 may be formed to overlap with wires such as the gate line and the data line of the display panel. An open region of the lattice type hardness compensation layer 510 may overlap with a pixel region such as a pixel electrode of the display panel.

The lattice or lattice type of the hardness compensation layer 510 overlaps the wire, and a width of the lattice may be, for example, about 90% or less of a width of the wire (e.g., the gate line, the data line, or the like). That is, the lattice of the opaque hardness compensation layer 510 may be prevented or substantially prevented from being seen by overlapping with the wire of the display panel.

The elastic coefficient of the hardness compensation layer 510 may be larger than the elastic coefficient of the base film 520 as will be described further later. As the elastic coefficient value is increased, hardness increases and ductility is reduced. According to the exemplary embodiment of the present invention, the hardness compensation layer 510 has the high elastic coefficient and thus, has high hardness and low ductility. On the other hand, the base film 520 according to the exemplary embodiment of the present invention has the relatively low elastic coefficient as compared to the hardness compensation layer 510, and thus has low hardness and high ductility. Therefore, the window according to the exemplary embodiment of the present invention may provide the desired hardness in the window 500 through the hardness compensation layer 510, and may provide the desired ductility through the base film 520.

The base film 520 is formed of a plastic film such as polyethylene terephthalate (PEF), polycarbonate (PC), polyimide (PI), poly(methylmethacrylate) (PMMA), and/or the like.

The coating layer 530 is formed of a material such as an organic hybrid resin, an inorganic hybrid resin, an acryl resin, and/or the like.

Further, a functional layer such as an anti-reflection layer preventing or substantially preventing external light from being reflected and/or an anti-fingerprint layer preventing or substantially preventing a user's fingerprint from remaining may be further included.

The thickness of the cover window 500 according to the exemplary embodiment of the present invention may be about 500 μm or less. This is because it is difficult for the cover window 500 having a thickness that is greater than the aforementioned thickness to have flexibility and ductility.

In the cover window 500 having the aforementioned thickness, the thickness of the hardness compensation layer 510 may be less than a sum of the thicknesses of the base film 520 and the coating layer 530. This is because in the case in which the thickness of the hardness compensation layer 510 is greater than the thickness of the base film 520 and the coating layer 530, it is difficult for the flexible display device to have the desired ductility.

The aforementioned cover window has the desired ductility and flexibility of the flexible or foldable display device and has a hardness at a preset level or more, and thus the display device having a better quality may be provided.

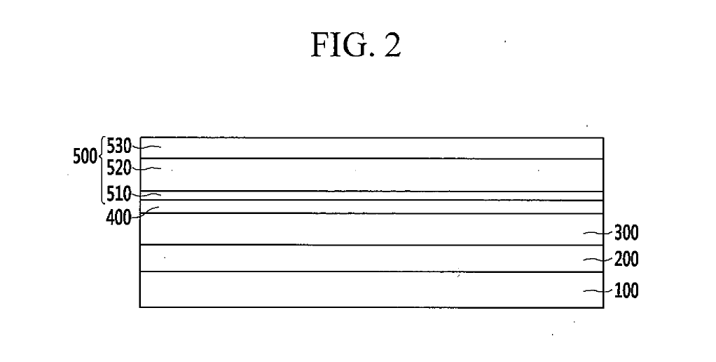

Hereinafter, a cover window according to another exemplary embodiment of the present invention and a display device including the same will be described with reference to FIG. 2. FIG. 2 is a schematic cross-sectional view of a display device according to another exemplary embodiment of the present invention. Hereinafter, a description of the display panel 100, the touch sensing layer 200, the polarizing plate 300, and the adhesive layer 400 that are the same as or similar to those of the exemplary embodiment of the present invention may not be provided again.

The window 500 according to the exemplary embodiment of the present invention includes a hardness compensation layer 510, a base film 520 positioned on the hardness compensation layer 510, and a coating layer 530 positioned on the base film 520. According to the exemplary embodiment, a separate functional layer positioned on the coating layer 530 may be further included.

The hardness compensation layer 510 provides hardness that is strong against external force or impact to the window 500. In the case of the window 500, a base film formed of a plastic material is used to implement flexibility, but has durability that is weaker than that of glass, and thus durability needs to be reinforced. Therefore, the thickness of the base film may be increased to reinforce durability, but in this case, there is a problem in that bending stiffness is increased to reduce flexibility of the flexible film. Herein, bending stiffness represents restoration force after bending.

Accordingly, in the exemplary embodiment of the present invention, flexibility is implemented through the base film having a small thickness, and hardness of the window is improved (e.g., increased) through the hardness compensation layer 510 positioned at a rear surface of the base film 520.

The hardness compensation layer 510 may be formed of any suitable material for improving hardness of the window 500, but for example, a material having a high elastic coefficient, such as an inorganic compound, may be used. For example, the inorganic compound may be silicon nitride (SiNx) or the like.

A planar type (kind) of the hardness compensation layer 510 may be a plate or plate type (e.g., a plate shape or in the shape of a plate). In the case in which the material of the hardness compensation layer 510 is the inorganic compound, because the material is a transparent material and is not seen from the outside, the hardness compensation layer may be provided as the plate or plate type (kind) for provision of higher hardness.

The plate type hardness compensation layer 510 may be provided as a film type (e.g., as a film), or may be formed without a limitation with respect to a manufacturing process such as coating or deposition.

The elastic coefficient of the hardness compensation layer 510 may be greater than the elastic coefficient of the base film 520 as will be described later in more detail. As an elastic coefficient value is increased, hardness is high and ductility is low. According to the exemplary embodiment of the present invention, the hardness compensation layer 510 has the high elastic coefficient and thus has high hardness and low ductility. On the other hand, the base film 520 according to the exemplary embodiment of the present invention has the relatively low elastic coefficient as compared to the hardness compensation layer 510, and thus has low hardness and high ductility. Therefore, the window according to the exemplary embodiment of the present invention may provide the desired hardness in the window 500 through the hardness compensation layer 510, and may provide the desired ductility through the base film 520.

The base film 520 is formed of a plastic film such as polyethylene terephthalate (PEF), polycarbonate (PC), polyimide (PI), poly(methylmethacrylate) (PMMA), and/or the like.

The coating layer 530 is formed of a material such as an organic hybrid resin, an inorganic hybrid resin, an acryl resin, and/or the like.

Although not illustrated in the present specification, a functional layer such as an anti-reflection layer preventing or substantially preventing external light from being reflected and/or an anti-fingerprint layer preventing or substantially preventing a user's fingerprint from remaining may be further included.

The thickness of the cover window 500 according to the exemplary embodiment of the present invention may be about 500 μm or less. This is because it is difficult for the cover window 500 having a thickness that is greater than the aforementioned thickness to have flexibility and ductility.

In the cover window 500 having the aforementioned thickness, the thickness of the hardness compensation layer 510 may be about 10% or less of the thickness of the base film 520. This is because in the case in which the thickness of the hardness compensation layer 510 made of an inorganic compound material is about 10% or more of the thickness of the base film 520, because flexibility and ductility are reduced, it is difficult to implement the flexible or foldable display device.

The aforementioned cover window has the desired ductility and flexibility of the flexible or foldable display device and has a hardness at a preset level or more, and thus the display device having a better quality may be provided.

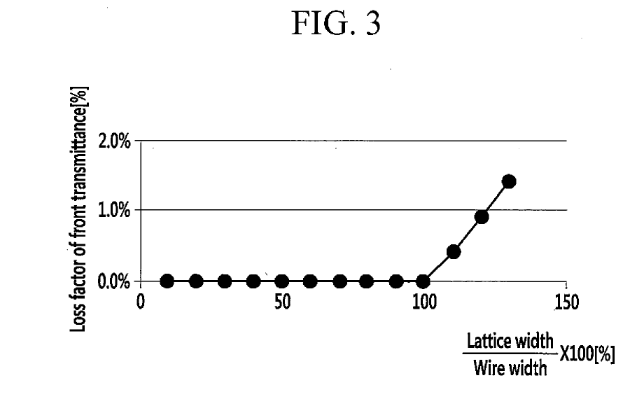

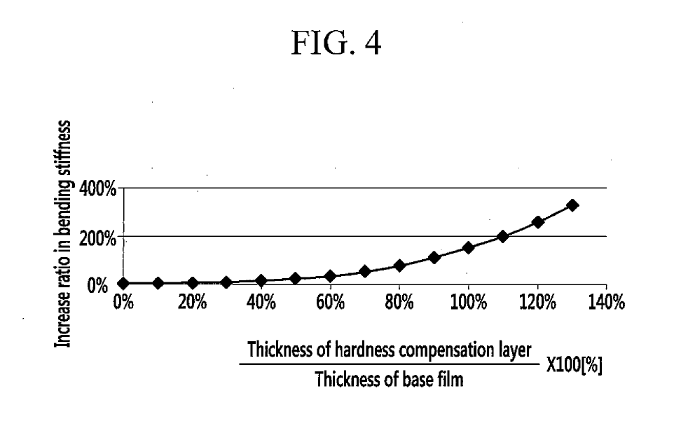

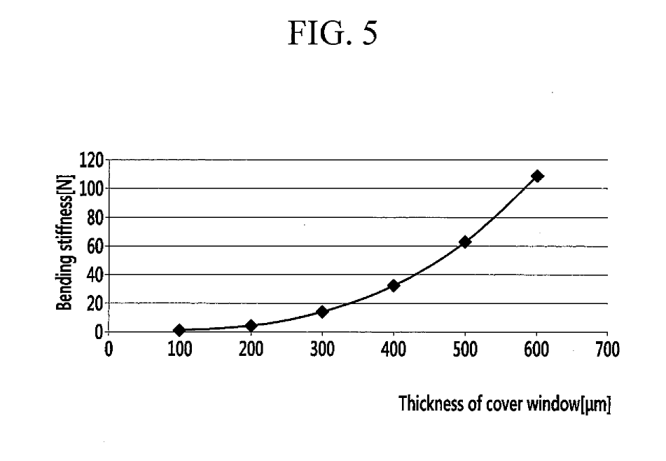

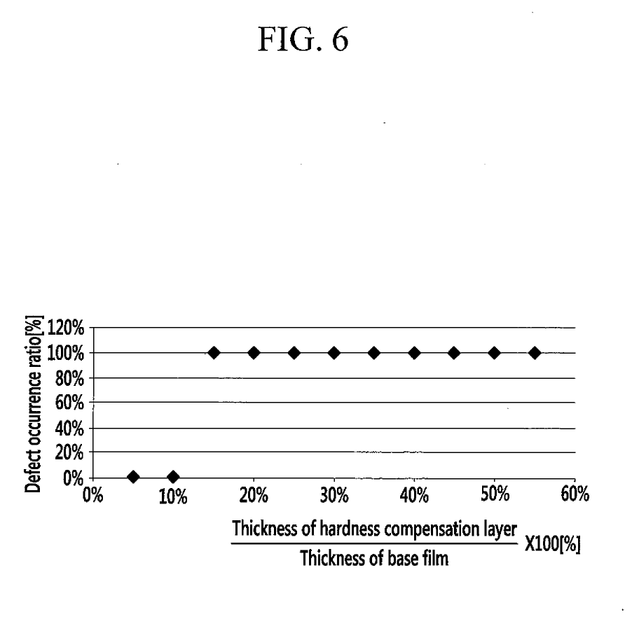

Hereinafter, a constitution of the cover window according to the exemplary embodiments of the present invention will be described with reference to FIGS. 3 to 6. FIG. 3 is a graph of a loss factor of front transmittance according to a width change. FIG. 4 is a graph of an increase ratio in bending stiffness according to the thickness. FIG. 5 is a graph of bending stiffness according to the thickness of the cover window according to the exemplary embodiment of the present invention. FIG. 6 is a graph of a defect occurrence ratio according to the thickness of the cover window according to another exemplary embodiment of the present invention.

First, a loss of transmittance according to a lattice width of the hardness compensation layer in the exemplary embodiment of the present invention will be described with reference to FIG. 3.

As illustrated in FIG. 3, it may be seen that until a width ratio is about 100%, in which the lattice width of the hardness compensation layer according to the exemplary embodiment of the present invention is the same as a wire width of the display panel, the loss of transmittance viewed from a front surface is almost 0.

However, it may be seen that from a time point at which the lattice width of the hardness compensation layer is increased as compared to the wire width of the display panel, the loss of transmittance viewed from the front surface is increased to about 2.0%. Therefore, like the exemplary embodiment of the present invention, the lattice width of the hardness compensation layer may be configured to be the same as or less than the wire width of the display panel, and in this case, transmittance may be prevented from being reduced.

Next, FIG. 4 is a graph of an increase ratio in bending stiffness according to an increase in thickness of the hardness compensation layer.

According to FIG. 4, the increase ratio in bending stiffness of the cover window is increased according to the increase in thickness of the hardness compensation layer, and for example, in the case in which the thickness of the hardness compensation layer and the thickness of the base film and the coating layer are the same or substantially the same as each other, the increase ratio in bending stiffness is about 150%.

In the case in which the thickness of the hardness compensation layer is greater than the thickness of the base film and the coating layer, the increase ratio in bending stiffness is more than about 150%, and in the case in which the increase ratio in , bending stiffness is more than about 150%, because repulsive force is excessive, it is difficult to apply the hardness compensation layer to the display device.

Therefore, like the exemplary embodiment of the present invention, the thickness of the hardness compensation layer may be the same as or less than the thickness of the base film and the coating layer, and according to this constitution, bending stiffness of the cover window may be the desired thickness in the display device.

Next, a bending stiffness value according to the thickness of the cover window according to the exemplary embodiment of the present invention will be described with reference to FIG. 5. According to FIG. 5, as the thickness of the cover window is increased, the bending stiffness value tends to be increased. For example, the cover window according to the exemplary embodiment of the present invention is used in the foldable or flexible display device, and thus it was confirmed whether the cover window is broken by bending of the device and the like.

In this case, it was confirmed that until the thickness of the cover window was about 500 μm, the device was not broken even though the cover window was bent, but in the case in which the thickness of the cover window was more than about 500 μm, the window was broken.

Therefore, according to an exemplary embodiment of the present invention, it is preferable in one embodiments that the thickness of the cover window used in the foldable or flexible display device be about 500 μm or less.

Next, a thickness of a hardness compensation layer made of an inorganic compound material according to another exemplary embodiment of the present invention will be described with reference to FIG. 6.

As a result of comparing the thickness of the hardness compensation layer to the thickness of the base film, it was confirmed that until the ratio of the thickness of the hardness compensation layer to that of the base film was about 10%, the cover window was not broken, but in the case in which the thickness of the hardness compensation layer to that of the base film was more than about 10%, the cover window applied to the foldable or flexible display device was broken. This is because as the thickness of the hardness compensation layer having high hardness and low ductility is increased, the window including the same has increased hardness but reduced ductility.

Therefore, according to an exemplary embodiment of the present invention, the thickness of the hardness compensation layer made of the inorganic compound material may be about 10% or less of the thickness of the base film. This is configured to satisfy desired ductility and hardness of the flexible or foldable display device.

The aforementioned cover window and the display device including the same may provide, a foldable or flexible display device, with desired ductility such as bendability, and hardness that is strong against external force and the like.

The terminology used herein is for the purpose of describing particular embodiments and is not intended to be limiting of the inventive concept. As used herein, the singular forms “a” and “an” are intended to include the plural forms as well, unless the context clearly indicates otherwise. It will be further understood that the terms “include,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list. Further, the use of “may” when describing embodiments of the inventive concept refers to “one or more embodiments of the inventive concept.” Also, the term “exemplary” is intended to refer to an example or illustration.

It will be understood that when an element or layer is referred to as being “on”, “connected to”, “coupled to”, or “adjacent to” another element or layer, it can be directly on, connected to, coupled to, or adjacent to the other element or layer, or one or more intervening elements or layers may be present.

As used herein, the term “substantially,” “about,” and similar terms are used as terms of approximation and not as terms of degree, and are intended to account for the inherent variations in measured or calculated values that would be recognized by those of ordinary skill in the art.

As used herein, the terms “use,” “using,” and “used” may be considered synonymous with the terms “utilize,” “utilizing,” and “utilized,” respectively.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. §112, first paragraph, and 35 U.S.C. §132(a).

While this invention has been described in connection with what is presently considered to be practical exemplary embodiments, it is to be understood that the invention is not limited to the disclosed embodiments, but, on the contrary, is intended to cover various suitable modifications and equivalent arrangements included within the spirit and scope of the appended claims, and equivalents thereof.

Description of some of the symbols

| | |
|---|---|
| 10: Display panel | 20: Cover window |
| 21: Base film | 22: Coating layer |
| 30: Flexible printed circuit | 50: Printed circuit board |

What is claimed is:

1. A cover window comprising:
a hardness compensation layer,
a base film on the hardness compensation layer, and
a coating layer on the base film,
wherein an elastic coefficient of the hardness compensation layer is greater than an elastic coefficient of the base film.

2. The cover window of claim 1, wherein a material of the hardness compensation layer comprises a metal and/or a metal compound.

3. The cover window of claim 2, wherein the hardness compensation layer is a lattice.

4. The cover window of claim 1, wherein a material of the hardness compensation layer comprises an inorganic compound.

5. The cover window of claim 4, wherein the hardness compensation layer is a plate.

6. The cover window of claim 4, wherein a thickness of the hardness compensation layer is about 10% or less of a thickness of the base film.

7. The cover window of claim 1, wherein a thickness of the hardness compensation layer is less than a sum of thicknesses of the base film and the coating layer.

8. The cover window of claim 1, wherein a thickness of the cover window is about 500 μm or less.

9. A display device comprising:
a display panel, and
a cover window on the display panel,
wherein the cover window comprises:
a hardness compensation layer,
a base film on the hardness compensation layer, and
a coating layer on the base film.

10. The display device of claim 9, wherein an elastic coefficient of the hardness compensation layer is greater than an elastic coefficient of the base film.

11. The display device of claim 9, wherein a material of the hardness compensation layer comprises a metal and/or a metal compound.

12. The display device of claim 11, wherein the hardness compensation layer is a lattice.

13. The display device of claim 9, wherein a material of the hardness compensation layer comprises an inorganic compound.

14. The display device of claim 13, wherein the hardness compensation layer is a plate.

15. The display device of claim 13, wherein a thickness of the hardness compensation layer is about 10% or less of a thickness of the base film.

16. The display device of claim 9, wherein a thickness of the hardness compensation layer is less than a sum of thicknesses of the base film and the coating layer.

17. The display device of claim 9, wherein a thickness of the cover window is about 500 μm or less.

18. The display device of claim 12,
wherein the display panel comprises a gate line, a semiconductor layer on the gate line, and a data line on the semiconductor layer, and
wherein a width of the lattice is about 90% or less of a width of any one of the gate line and the data line.
